(19) United States
(12) Patent Application Publication
(10) Pub. No.: US 2024/0012074 A1
(43) Pub. Date: Jan. 11, 2024

(54) IMPROVED RF COIL FOR INSIDE-OUT NMR/MRI SYSTEMS

(71) Applicant: Clear-Cut Medical Ltd., Rehovot (IL)

(72) Inventors: Tal Bareket, Tel Aviv (IL); Saul Stokar, Raanana (IL); Zachi Peles, Avihayil (IL)

(73) Assignee: Clear-Cut Medical Ltd., Rehovot (IL)

(21) Appl. No.: 18/251,579

(22) PCT Filed: Nov. 1, 2021
(86) PCT No.: PCT/IB2021/060100

§ 371 Date: May 3, 2023

Related U.S. Application Data
(60) Provisional application No. 63/109,391, filed on Nov. 4, 2020.

(51) Int. Cl. G01R 33/34

(52) U.S. Cl. CPC G01R 33/34084; G01R 33/3403

(57) ABSTRACT

A system for NMR/MRI, having X, Y, Z directions, includes an RF coil having a B₀ static magnetic field in the Z direction and a transverse B₁ RF magnetic field in the XY directions. Currents in the RF coil are distributed so that the transverse B₁ field is substantially uniform in the XY plane.

### FIELD OF THE INVENTION

The present invention relates generally to magnetic resonance imaging (MRI) scanning devices, and particularly to an improved RF coil for inside-out MR scanners.

### BACKGROUND OF THE INVENTION

The RF coil plays a dual role in NMR (nuclear magnetic resonance) and MRI. Its geometry determines the shape and size of the volume excited by the RF (radio frequency) pulses if the coil is used for transmission (Tx) as well as the volume from which signal is detected if the coil is used for signal reception (Rx).

It is well known to those skilled in the arts of NMR or MRI that only components of the RF magnetic field (denoted B₁) that are perpendicular to the static magnetic field (denoted B₀) are useful for NMR and MRI. Since the direction of B₀ is traditionally called the Z direction, this means that the components of B₁ that are useful for NMR/MRI are B₁ₓ and B_{1y}, denoted collectively as B_{1xy}.

In some NMR and MRI systems the same RF coil is used for transmission and reception. In this case, it is well known via the so-called “principle of reciprocity” that the phase of B₁ cancels between Tx and Rx, and the coil's properties can be evaluated by examining the amplitude of B_{1xy}, denoted |B_{1xy}|.

Some NMR/MRI scanners are known as “inside-out” systems, where the magnetic fields (B₀ and/or B₁) are generated from outside the sensitive volume. Applications of such systems include (but are not limited to) stray field NMR, oil well logging, material testing, intra-vascular catheters used for tissue characterization at the vessel wall, as well as systems that examine in-vivo tissue specimens using MR, such as Clear Cut Medical's ClearSight system.

The RF coils used in the prior art inside-out systems are typically either round or square coils, sometimes repeated in a multi-layer fashion (along the Z axis) as a solenoid. Instead of a pure circle or square, a Archimedean, hyperbolic or logarithmic spiral, a square rectangle, etc. is often used. The idea for such a coil comes from standard NMR/MRI (i.e., not inside-out), where the RF coil fully encloses the sample. In this case, the relevant B₁ (B_{1z} where Z is the axis of the RF coil) is substantially uniform across the sample.

However, in inside-out systems the situation is different. First, the relevant component of the field is B_{1xy}. Second, the RF field is substantially non-uniform across the sample. The coil current and B₁ field of such a single layer 4 mm diameter spiral are shown respectively, in FIGS. 1 and 2, which show a plot of |B_{1xy}| (per unit current I) vs X and Y for Z=0.5 i.e. 0.5 mm above the plane of the spiral. The advantage of this configuration is the high value of B₁ per unit current that is obtained, which is favorable for SNR (signal-to-noise ratio) during signal reception. However, there are at least two disadvantages of this design. The first disadvantage is that the B₁ field of the coil along the line perpendicular to the coil's axis through the coil's center is purely along the Z axis. That is, for the purpose of NMR/MRI the coil has a “hole” along the line X=Y=0 and is low near that line. The second disadvantage of this design is the roll off on the sides (inner and outer) of the volcano-shaped B₁ field. These disadvantages are all illustrated in FIG. 2.

The B₁ field has the shape of a “volcano”—the field is small or zero at the center, it has a narrow circular ridge of high B₁ at the center of the field of view and it falls off in a Gaussian-like fashion from the ridge, both towards the center and towards the outside. The B₁ field in the 4 corners of the nominal field of view (approximately 4 mm×4 mm in this case) is quite small. This situation is disadvantageous: any tissue found in the area of low of zero B₁ will not contribute (or contribute with small weight) to the signal induced in the antenna and thus will either not be “seen” at all or have a low relative weight (compared to tissue found in the area of high B₁). If the same coil is used for both Tx and Rx, the penalty is even larger: the signal will not be properly excited in the areas where B₁ is low or zero and no or little signal will be received from there during Rx.

To overcome the null on the line through the RF coil's isocenter, some prior art designs lay out two coils side-by-side, in a so-called “FIG. 8 configuration”. Alternately, four coils are laid out in a plane to form a so-called “butterfly” coil. While these coil designs remove the null at the isocenter, they suffer from two other problems: (a) the B₁ field remains substantially non-uniform and (b) there are so-called “side-lobes” in the B₁ field, where the field is non-negligible far from the area of interest (i.e. outside the nominal field of view of the coil). The existence of these side lobes means that if used for NMR/MRI, signal will be both induced and received from volumes outside the nominal field of view, competing with signals from volumes within the nominal field of view.

### SUMMARY OF THE INVENTION

The present invention also seeks to provide an improved RF coil for an inside-out NMR/MRI system, as described in more detail further below.

The invention substantially improves the “definition” of the B₁ field. Advantages of the new design include, but are not limited to:
a. there is no substantial hole or dip in the B₁ field at the center of the field of view;
b. the fall-off of the B₁ field at the edges of the field of view is quite steep, which means the field of view is well-defined; and
c. the B₁ field substantially and uniformly fills up the field of view, without leaving holes or dips in the corners.

There is thus provided in accordance with an embodiment of the present invention a system for NMR/MRI having X, Y, Z directions, including an RF coil having a B₀ static magnetic field in the Z direction and a transverse B₁ RF magnetic field in the XY directions, wherein currents in the RF coil are distributed so that the transverse B₁ field is substantially uniform in the XY plane.

In accordance with an embodiment of the present invention a volume of interest of the RF coil lies substantially outside the RF coil.

In accordance with an embodiment of the present invention the currents that generate the RF magnetic field consist of substantially parallel segments, perpendicular to the static magnetic field.

In accordance with an embodiment of the present invention the direction of the current in each segment may be selected to optimize the B₁ field profile.

In accordance with an embodiment of the present invention the uniformity of the transverse B₁ field along the Z axis may be optimized for uniformity along the Z axis as well.

A volume of interest may be well defined in the X, Y and Z planes by at least 80% of total received signal. The volume of interest may be optimized so as to receive as uniform B_{1xy} field as possible. The volume of interest may be optimized so as to receive the maximal B1xy field possible.

The number of “lines” in each layer may be variable. The number of layers or the distance between layers may be variable. The distance between lines in each layer may be variable. The dimension (width, length or thickness) of each line in each layer may be variable. The material of each line in each layer may be variable. The current direction of each line in each layer may be variable. The material of the subtract containing the lines in each layer may be variable.

In accordance with an embodiment of the present invention the coil may be cooled using a cooling device such as thermoelectric cooling device, liquid nitrogen or helium.

In accordance with an embodiment of the present invention the plane of the coil may be rotated away from being perpendicular to the static magnetic field.

In accordance with an embodiment of the present invention the coil core may be a ferromagnetic material.

In accordance with an embodiment of the present invention the coil may be in a vacuum state. The coil may be printed and/or wound. The coil may be part of a multi-coil array.

### BRIEF DESCRIPTION OF DRAWINGS

The present invention will be understood and appreciated more fully from the following detailed description, taken in conjunction with the drawings in which:

FIG. 1 is a simplified graphical illustration of current for a single-layer spiral RF coil of the prior art;

FIG. 2 is a simplified graphical illustration of magnitude of B_{1xy} vs X and Y for Z=0.5 mm (i.e., in the plane 0.5 mm above the plane of the spiral) for the prior art spiral RF coil of FIG. 1, wherein the field was obtained from the current using a Biot-Savart simulation;

FIG. 3 is a simplified graphical illustration of a magnetic field generated by a single straight conductor, showing current in a single line along Y for X=0;

FIG. 4 is a simplified graphical illustration of the B₁ field produced by this single line of current;

FIG. 5 is a simplified graphical illustration of current for 6 lines of current along the Y axis (note that the total X extent of the lines is small), in accordance with a non-limiting embodiment of the present invention;

FIG. 6 is a simplified graphical illustration of B_{1xy} for 6 lines of current of FIG. 5;

FIG. 7 is a simplified graphical illustration of current for a simple lines coil (12 lines), without return lines, in accordance with a non-limiting embodiment of the present invention;

FIG. 8 is a simplified graphical illustration of B₁ field map vs X and Y for the single layer lines coil, at Z=0.4 mm above the coil surface;

FIG. 9 is a simplified graphical illustration of current for a three layer lines coil (without return lines), in accordance with a non-limiting embodiment of the present invention;

FIG. 10 is a simplified graphical illustration of B_{1xy} for the multi-layer lines coil;

FIG. 11A is a simplified graphical illustration of single (left side of FIG. 11A) and triple layer (right side of FIG. 11A) “lines” coils, in which the B₁ field of the triple layer coil is much larger than that of the single layer coil, in accordance with a non-limiting embodiment of the present invention;

FIG. 11B is a simplified graphical illustration of the profiles along Y-axis of the single (lower curve in FIG. 11B) and multi-layer (upper curve in FIG. 11B) “lines” coils, in which the profile of the B₁ field along the Y axis is larger, more square and with a sharper edge for the multi-layer coil as compared with the single layer coil.

FIG. 12 is a simplified graphical illustration of |B_{1xy}| for an eight layer spiral, in accordance with a non-limiting embodiment of the present invention; and

FIG. 13 is a simplified graphical illustration of |B_{1xy}| for a 3 layer lines coil, in accordance with a non-limiting embodiment of the present invention.

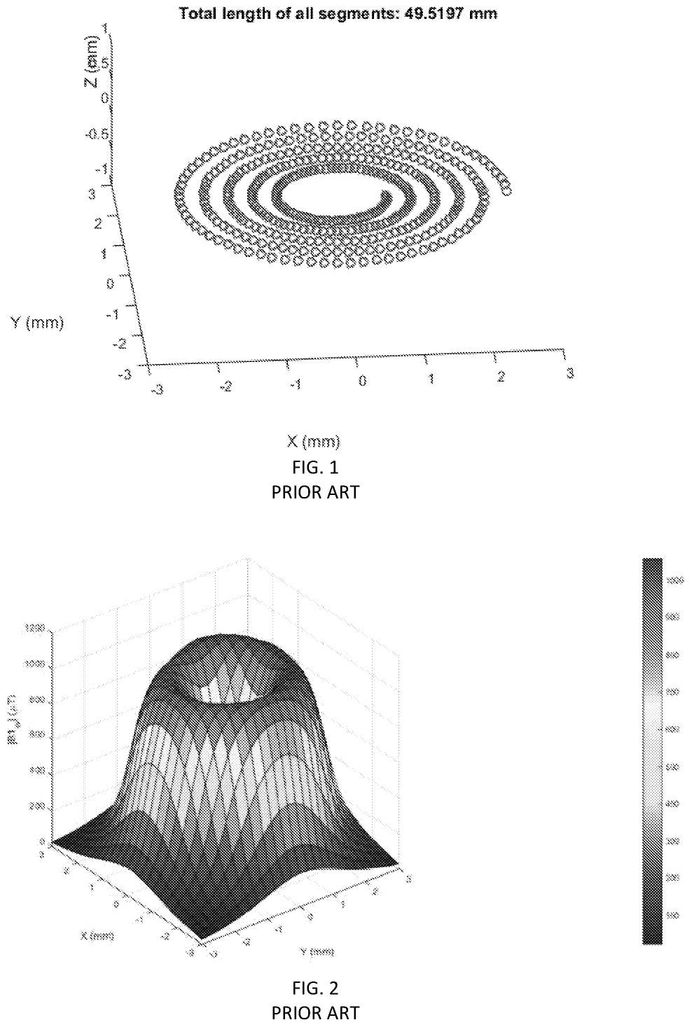

### DETAILED DESCRIPTION OF EMBODIMENTS

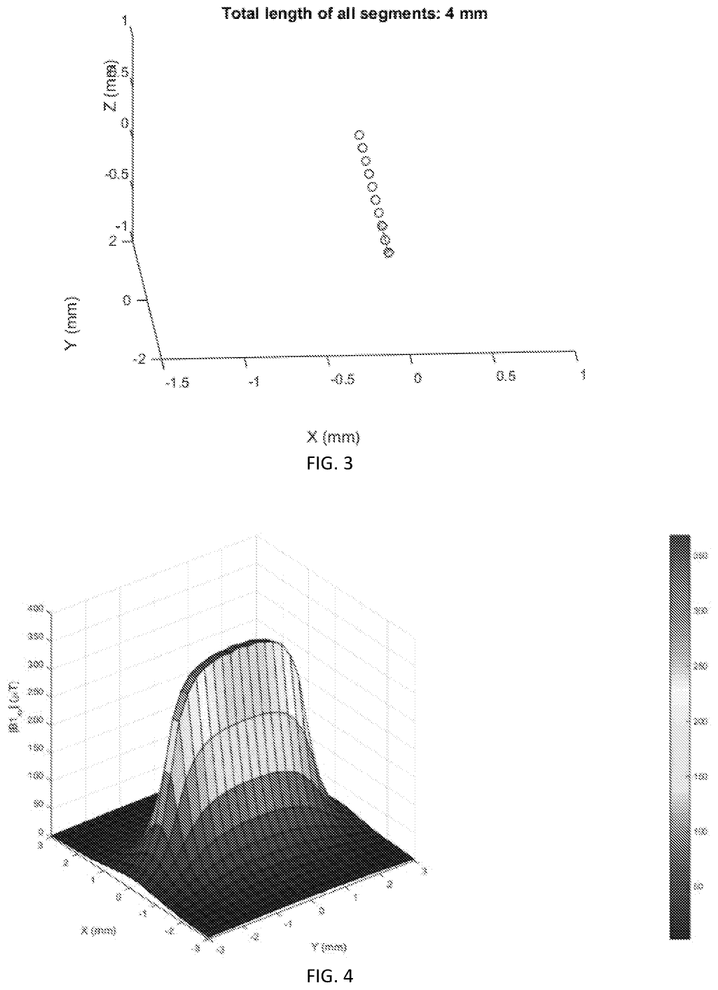

In order to understand principles of the invention, reference is first made to the magnetic field generated by a single straight conductor as seen in FIGS. 3 and 4.

FIG. 3 shows a finite straight conductor along the Y axis at X=0 (with no return path) and FIG. 4 shows the B₁ field this current produces.

This B1 field has a number of advantages; most importantly it is substantially uniform and well-defined, without holes or significant dips. The shape and dimensions of the B₁ field can be controlled by varying the length of current conductor.

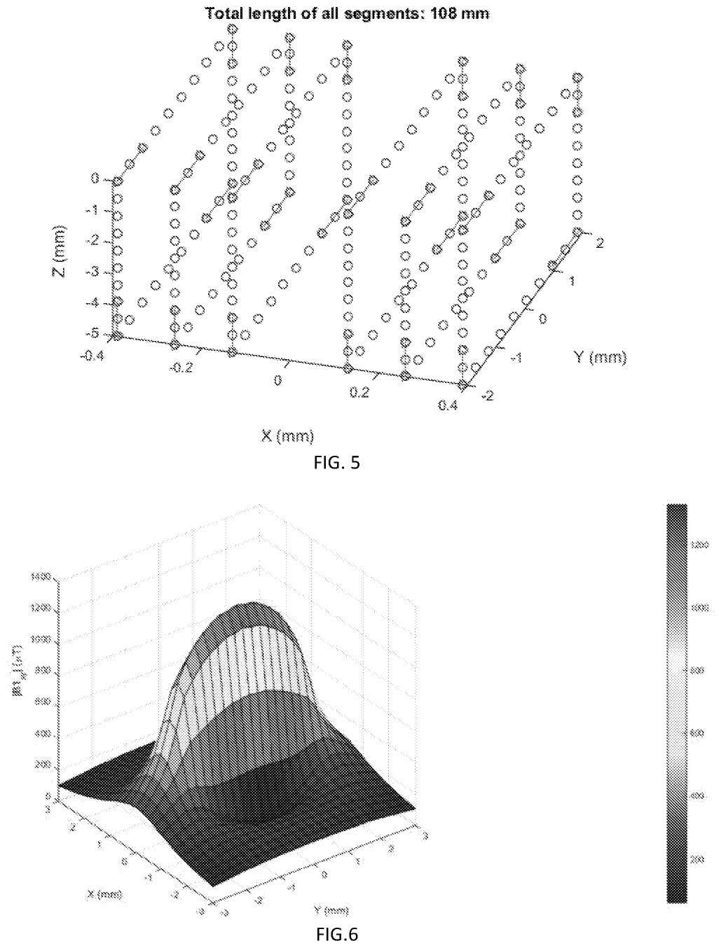

The invention may employ a field of a number of parallel conductors, which have multiple, nearly parallel lines of current, which widens the area of the B₁ field. FIGS. 5 and 6 show the current and B_{1xy} field for a configuration of 6 parallel lines of current along the Y axis at different X positions, including complete return paths below. (The extent of the lines in the X direction is only [−0.4,0.4] mm.) Note that the field-of-view is fairly rectangular and much more uniform that the field-of-view for the spiral coil. In addition, there is no hole/dip in the center of the field of view.

Since the B₁ field produced by a set of parallel lines has many attractive features for an inside-out NMR.MRI system, the inventors optimized the parameters of the lines—the number of lines, length of each line, inter-line distance, the number of layers, the conductivity for each line and the direction of the current (independently for each line). This is referred to as a “lines” coil. For each set of parameters, the B₁ field was calculated using an electromagnetic simulation and various figures of merit were calculated, using calculations well-known to those skilled in the art of RF coil design for NMR/MRI.

Single Layer Lines Coil:

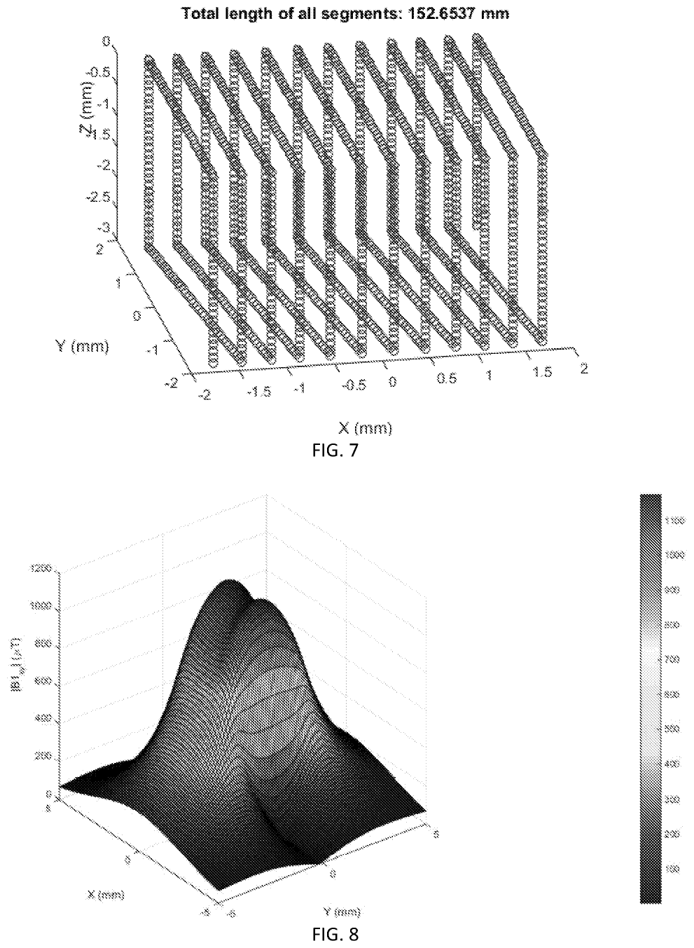

FIGS. 7 and 8 show the current and B₁ field for an implementation of the invention for a single-layer “lines” coil.

Multi-Layer Lines Coils:

If the coil's resistance is not critical, one can add multiple layers. The additional layers can be tailored to accomplish a number of aims, such as but not limited to, increasing the field per unit current (B₁/I), and/or improving the profile of the B₁ field, adding and subtracting (i.e., cancelling) field where needed to sharpen and flatten the profile. The field may be added or subtracted by setting the direction of the current in the segment being added.

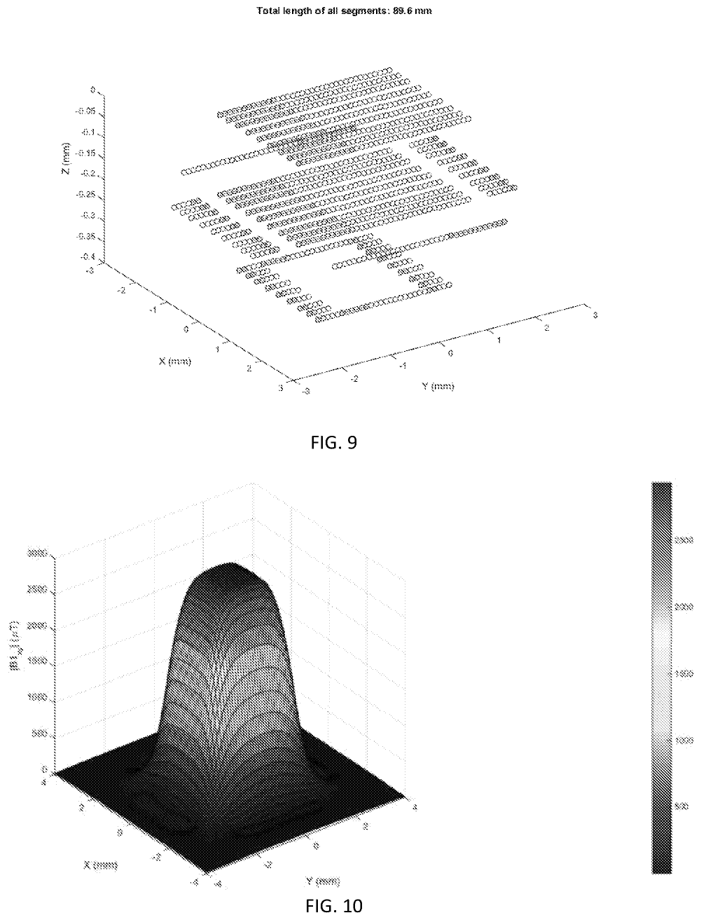

FIGS. 9 and 10 show the current for a more complex three-layer lines coil.

Comparison of the B₁ Field of Single and Multi-Layer “Lines” Coils:

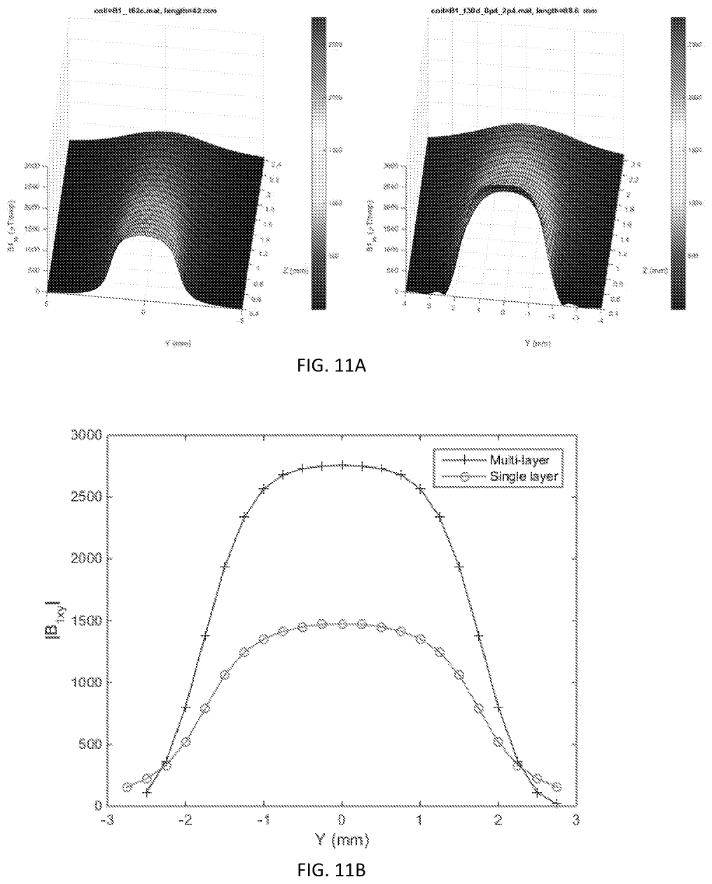

FIGS. 11A and 11B show the profiles of the field of view for the single and triple layer “lines” coils.

Note that the profile of the B₁ field along the Y axis is larger, more square and with a sharper edge for the multi-layer coil as compared with the single layer coil.

The Z Falloff:

Until now the description examines the X-Y dependence of B_{1xy}. The Z dependence of B_{1xy} is also of interest. It is of course expected from basic principles of electromagnetism that B_{1xy} falls off with Z. For the purpose of an “inside-out” system, which attempts to probe a specific range, ideally B_{1xy} should be as uniform as possible within that Z range and to fall off as rapidly as possible outside that range (e.g. for Z >Zₘₐₓ).

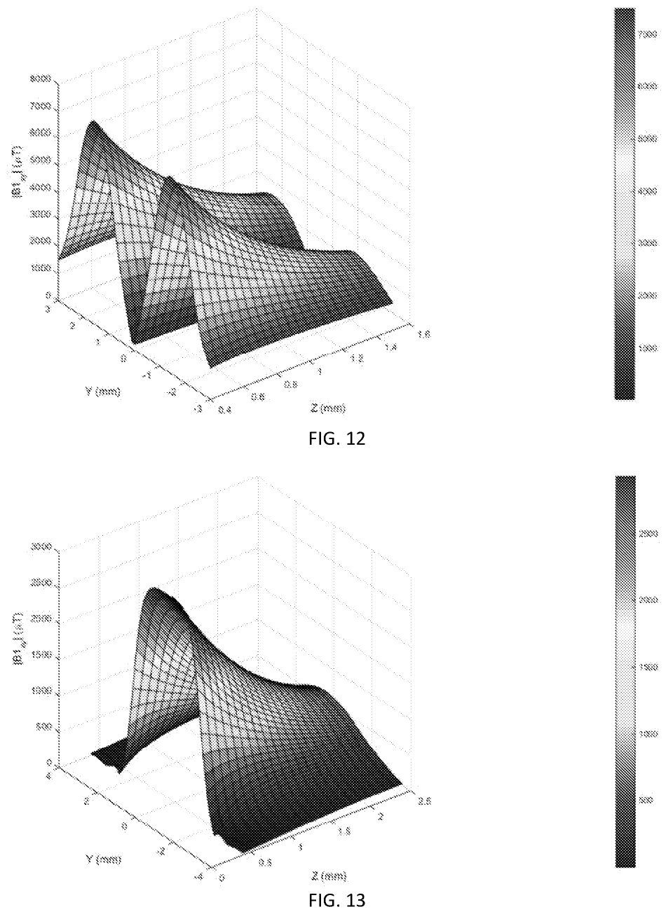

FIGS. 12 and 13 show |B_{1xy}| in the Y-Z plane (note the difference in the Z scale for the two plots). Note that the “line” coil has a lower B₁/I but a better (i.e. deeper) Z penetration.

It is noted that the direction of the current in each line segment determines the direction of the B_{1xy} field it produces. Thus by adding lines and/or layers one can either increase or decrease the B_{1yx} field depending on the direction of the current in each segment. In addition, by controlling the conductivity of each line one can control the current it produces and hence the B_{1xy} field it creates.

What is claimed is:

1. A system for NMR/MRI having X, Y, Z directions, comprising:
an RF coil having a B₀ static magnetic field in the Z direction and a transverse B₁ RF magnetic field in the XY directions, wherein currents in said RF coil are distributed so that the transverse B₁ field is substantially uniform in the XY plane.

2. The system according to claim 1, wherein a volume of interest of said RF coil lies substantially outside said RF coil.

3. The system according to claim 1 wherein the currents that generate the RF magnetic field consist of substantially parallel segments, perpendicular to said static magnetic field.

4. The system according to claim 1 wherein the direction of the current in each segment is selected to optimize the B₁ field profile.

5. The system according to claim 1 wherein the uniformity of the transverse B₁ field along the Z axis is optimized for uniformity along the Z axis as well.

6. The system according to claim 1 wherein a volume of interest is well defined in the X, Y and Z planes by at least 80% of total received signal.

7. The system according to claim 6 wherein the volume of interest is optimized so as to receive as uniform B_{1xy} field as possible.

8. The system according to claim 6 wherein the volume of interest is optimized so as to receive the maximal B1xy field possible.

9. The system according to claim 6 wherein the number of “lines” in each layer is variable.

10. The system according to claim 6 wherein the number of layers is variable.

11. The system according to claim 6 wherein the distance between layers is variable.

12. The system according to claim 6 wherein the distance between lines in each layer is variable.

13. The system according to claim 6 wherein the dimension (width, length or thickness) of each line in each layer is variable.

14. The system according to claim 6 wherein the material of each line in each layer is variable.

15. The system according to claim 6 wherein the current direction of each line in each layer is variable.

16. The system according to claim 6 wherein the material of the subtract containing the lines in each layer is variable.

17. The system according to claim 6 wherein the coil is cooled using a cooling device such as thermoelectric cooling device, liquid nitrogen or helium.

18. The system according to claim 6 wherein the plane of the coil is rotated away from being perpendicular to the static magnetic field.

19. The system according to claim 6 wherein the coil is in a vacuum state.

20. The system according to claim 6 wherein the coil is part of a multi-coil array.
